(19) United States
(12) Patent Application Publication
(10) Pub. No.: US 2009/0093134 A1
(43) Pub. Date: Apr. 9, 2009

(54) SEMICONDUCTOR MANUFACTURING APPARATUS AND METHOD FOR CURING MATERIALS WITH UV LIGHT

(75) Inventors: Kiyohiro Matsushita, Tokyo (JP); Kenichi Kagami, Tokyo (JP)

Correspondence Address: KNOBBE MARTENS OLSON & BEAR LLP, 2040 MAIN STREET, FOURTEENTH FLOOR, IRVINE, CA, 92614, US

(73) Assignee: ASM Japan K.K, Tokyo (JP)

(21) Appl. No.: 11/868,233

(22) Filed: Oct. 5, 2007

(51) Int. Cl. H01L 21/473

(52) U.S. Cl. 438/788; 427/508; 257/E21.471

(57) ABSTRACT

Low dielectric constant materials are cured in a process chamber during semiconductor processing. The low dielectric constant materials are cured by irradiation with UV light. The atmosphere in the process chamber has a CO₂ concentration of about 1-16% by volume during the irradiation. The CO₂ limits the formation of —Si—H and —Si—OH groups in the low dielectric constant material, thereby reducing the occurrence of moisture absorption and oxidation in the low dielectric constant material.

### BACKGROUND OF THE INVENTION

1. Field of the Invention

This invention relates to semiconductor processing and, more particularly, to semiconductor processing equipment and methods for curing materials on semiconductor substrates using ultraviolet light.

2. Description of the Related Art

Ultraviolet (UV) light processing apparatuses have been used in making substances using UV-light ray modification or photochemical reactions of materials on a variety of treated articles. As a result of the finer wiring designs and multi-layer wiring structures necessitated by increased device integration in recent years, a reduction in interlayer capacitance has become vital. The reduction in interlayer capacitance facilitates increasing the speeds of devices such as integrated circuits and lowering the power consumption of the devices.

Low-k (low dielectric constant film) materials have been used to lower the interlayer capacitance. These materials have a lower dielectric constant compared to traditional materials, such as silicon oxide. However, they also have a reduced mechanical strength (typically measured in terms of elastic modulus, or EM) compared to traditional materials such as silicon oxide. As a result, low-k materials typically have a greater difficulty withstanding stresses during chemical mechanical polishing (CMP), wiring bonding, and packaging during post-processing.

One method of overcoming these problems is to cure the low-k material with UV irradiation (UV curing), thereby increasing the material's mechanical strength. UV curing is described in, e.g., U.S. Pat. Nos. 6,759,098 and 6,296,909, the entire disclosures of which are incorporated herein by reference. It is possible to shrink and cure low-k materials with UV irradiation. The UV curing can raise the materials' mechanical strength (EM) by 50-200%.

Nevertheless, there is an ever-present demand for increased curing efficiency to facilitate increases in processing throughput. In addition, there is a continuing demand to improve the properties of UV cured low-k films.

Accordingly, there is a need for UV curing systems and methods that allow for increased efficiency and desired materials properties.

### SUMMARY OF SOME EMBODIMENTS

In accordance with some embodiments of the invention, a method is provided for semiconductor processing. The method comprises providing a low dielectric constant film on a substrate in a process chamber. The low dielectric constant film is cured by irradiating the low dielectric constant film with UV light. The low dielectric constant film is exposed to a process gas having about 1-16% CO₂ by volume during curing the low dielectric constant film.

In accordance with other embodiments of the invention, a method is provided for integrated circuit fabrication. The method comprises providing a substrate in a process chamber having a process chamber atmosphere with a CO₂ concentration between about 1% and about 16%. The substrate has an exposed low dielectric constant material. The low dielectric constant material is irradiated with UV light to form Si—O bonds while suppressing formation of —Si—H and —Si—OH groups relative to UV light irradiation of the low dielectric constant material in an atmosphere consisting of inert gas. The low dielectric constant material is reacted with CO₂ while irradiating the low dielectric constant material, thereby releasing H₂O from the low dielectric constant material

In accordance with other embodiments of the invention, a system for semiconductor processing is provided. The system includes a UV radiation chamber having a UV light source. A source of CO₂ in gas communication with the UV radiation chamber is provided. A controller is programmed to irradiate a low dielectric material in the UV radiation chamber with UV light while maintaining a concentration of CO₂ in the UV radiation chamber between about 1 and about 16% by volume.

### BRIEF DESCRIPTION OF THE DRAWINGS

FIG. 1 is a schematic, cross-sectional side view of a semiconductor processing reactor, in accordance with embodiments of the invention.

FIG. 2 is graph combining various FT-IR spectrographs of low-k dielectric materials after curing the low-k dielectric materials, in accordance with embodiments of the invention.

FIGS. 3 and 4 show the differences in FT-IR spectrographs of low-k dielectric materials before and after UV curing, in accordance with embodiments of the invention.

FIG. 5 is a graph showing the dielectric constant of a UV-cured low-k dielectric as a function of the CO₂ concentration in the atmosphere in which the low-k dielectric was cured.

FIG. 6 is a graph showing the mechanical strength of a UV-cured low-k dielectric as a function of the CO₂ concentration in the atmosphere in which the low-k dielectric was cured.

### DETAILED DESCRIPTION OF SOME EMBODIMENTS

Moisture absorption and oxidation have been observed in UV-cured low dielectric constant materials (low-k materials), e.g., materials having a dielectric constant of 4 or less. The moisture absorption and oxidation can undesirably increase the dielectric constant of the materials and also cause stress-related changes over time. As a result, it has generally been considered necessary to prevent exposure to oxidants during UV curing. Thus, to prevent oxidation of the low-k materials, the UV curing process is typically performed in an inert atmosphere, devoid of oxygen species.

It has been found that —Si—H groups or —Si—OH groups in the low-k materials contribute also to moisture absorption and oxidation. Low-k materials include carbon and silicon materials, including organosilicate glass and other materials having a dielectric constant below 4. Exposure to UV light has been found to cause silicon in the low-k materials to bind with H or OH groups, thus forming —Si—H and —Si—OH groups, which are not favorable for the low-k materials. Without being limited by theory, it is believed that these groups can react to form or absorb water, which adversely impacts the dielectric constant of the material.

While exposing low-k materials to CO₂, which can form oxidizing oxygen species when exposed to UV light, has been considered undesirable due to concerns about oxidation, it has been found that UV curing in an atmosphere containing CO₂ is advantageous for material stability and for limiting increases in dielectric constant. It has been found that exposure to CO₂, in appropriate concentrations, can limit the production of —Si—H and —Si—OH groups, to decrease moisture absorption and adverse impacts on dielectric constant.

Advantageously, according to preferred embodiments of the invention, a low-k material is cured by exposure to UV light in a process chamber having an atmosphere containing about 1-16% CO₂ by volume or about 1-5% CO₂ by volume. Without being limited by theory, it is believed that the UV exposure in the CO₂-containing atmosphere causes the release of —H and —OH groups as H₂O, thus suppressing the production of —Si—H and —Si—OH, while encouraging the formation of —O—Si bonds. As a result, curing efficiency is improved by aiding the formation of a network of silicon atoms bonded to oxygen atoms (—Si—O—). Thus, preferred embodiments of the invention advantageously limit the production of Si—H and Si—OH groups and improve curing efficiency about 10% or more, relative to a similar UV curing process in an atmosphere containing only inert gas. In some embodiments, the dielectric constant of the low-k material can be about 2.8 or less after UV curing.

Reference will now be made to the Figures.

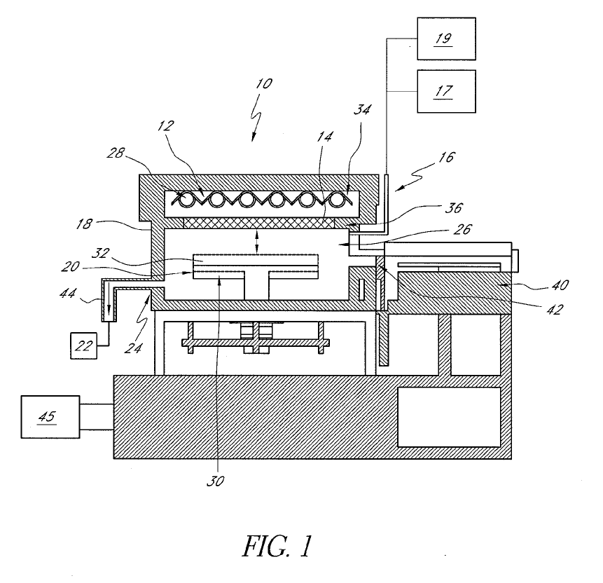

It will be appreciated that preferred embodiments of the invention can be applied to various UV curing apparatus known the art. An advantageous and non-limiting example of one such UV curing apparatus is illustrated in FIG. 1.

With reference to FIG. 1, a UV irradiation apparatus 10 is illustrated. The apparatus 10 includes a UV light emitting unit 12, an irradiation window 14, a gas introduction conduit 16, connected to a CO₂ source 17 and a process gas source 19 a reactor body 18, a susceptor 20, a vacuum pump 22, a pressure control valve 24 and a process chamber 26.

The UV light irradiation unit 12 is installed at a top of the chamber 26. The UV light unit 12 includes UV-light emitting bodies 28 which can emit light continuously and in pulses.

The susceptor 20 is installed parallel to and facing the light emitting bodies 28. The irradiating window 14, which can be formed of glass or other material which transmits UV light, is parallel to and interposed between the UV-light light emitting bodies 28. A substrate 32 is provided over the susceptor 20. The susceptor 20 can be provided with heaters 30 for heating the susceptor 20 an overlying substrate.

The irradiating window 14 allows uniform UV irradiation to be realized on the substrate 32. The irradiating window 14 may be, for example, formed of synthetic quartz and may shield the process chamber 26 from the ambient atmosphere while allowing UV light to pass through.

In the illustrated embodiment, the UV-light emitting bodies 28 inside the UV light irradiation unit 12 are tube-shaped. A plurality of the UV-light emitting bodies 28 are provided, as shown in FIG. 1, and the light emitting bodies 28 are positioned to allow for uniform illumination of the substrate 32. One or more reflective plates 34 (which can be akin to a shade on a lamp) are provided adjacent the UV-light emitting bodies 28 and are positioned to reflect UV light from the UV-light emitting bodies 28 towards the substrate 32. The angles of the reflective plates 34 can be adjusted to uniformly illuminate the substrate 32. The UV-light emitting bodies 28 are designed so as to be easily removed and replaced, to facilitate repair and maintenance.

In the apparatus 10, the pressure in the chamber 26 can be varied in a range from a vacuum to near atmospheric pressure or more. The chamber 26 is separated, by a flange 36 in which the irradiation window 14 is installed, from the UV-light emitting bodies 28 so as to separate the substrate processing section (including the chamber 26) and the UV emitting section (including the UV light emitting unit 12) of the apparatus 10. Gas is introduced via the flange 36, with a plurality of gas introduction holes provided therein, their positions being symmetrical so as to create a uniform flow of gas and a uniform processing atmosphere.

In some embodiments, a UV curing process is carried out as follows. The chamber 26 is filled with a gas selected from a group that includes Ar, CO, CO₂, C₂H₄, CH₄, H₂, He, Kr, Ne, N₂, O₂, Xe, alcohol gases and organic gases to create an atmosphere in the chamber 26 with a pressure of about 0.1 Torr to near atmospheric pressure or up to about 1000 Torr (including 1 Torr, 10 Torr, 50 Torr, 100 Torr, 1000 Torr or any other pressure in between). It will be appreciated that during irradiation with UV light, the atmosphere in the process chamber contains about 1-16% CO₂. The process chamber atmosphere can be formed by flowing a process gas mixture having about 1-16% CO₂ by volume into the process chamber, before and/or during UV irradiation of a substrate. In some other embodiments, a given gas atmosphere can first be established in the process chamber and then CO₂ can be added to the gas atmosphere to establish an atmosphere having about 1-16% CO₂ by volume. The CO₂ can be added before and/or after a substrate is loaded into the process chamber. In some preferred embodiments, the CO₂ and an inert gas constitute the process chamber atmosphere.

A processing target 32, or semiconductor substrate, having a low-k material, such as a deposited low-k film, is loaded from the load lock chamber 40 via the gate valve 42 and placed onto the susceptor 20. The low-k film can be formed by various methods known in the art. Suitable methods are disclosed in, e.g., U.S. Pat. No. 6,514,880, U.S. Pat. No. 6,455,445 and U.S. Pat. No. 7,144,620, the entire disclosures of which are incorporated by reference herein. The susceptor 20 is adjusted to have a temperature of about 0° C. to about 650° C. (including 10° C., 50° C., 100° C., 200° C., 300° C., 400° C., 500° C., 600° C. or any other temperature in between, but preferably between 300° C. and 450° C.), and then UV light with a wavelength of about 100-400 nm (including 150 nm, about 190 nm or less, 200 nm, 250 nm, 300 nm, 350 nm or any other wavelength in between, but preferably about 200 nm) is used to irradiate the low-k material on the semiconductor substrate 32.

The UV-light emitting bodies 28 can include various UV lamps known in the art. Examples of UV lamps include mercury lamps and excimer lamps. Excimer lamps include Xe excimer lamps, which output 172-nm DUV, characterized by high energy and rapid curing speed. Mercury lamps can vary in terms of lamp pressure from low pressure to very high pressure, and can emit light at wavelengths such as 185 nm, 254 nm, 365 nm.

With continued reference to FIG. 1, the substrate 32 is spaced from the UV-light emitting bodies 28 by a desired distance, which can be about 1-100 cm in some embodiments. The intensity of light on the substrate surface is about 1-1000 mW/cm² (including 10 mW/cm², 50 mW/cm², 100 mW/cm², 200 mW/cm², 500 mW/cm², 800 mW/cm² or any other output in between). The UV light is emitted continuously or in pulses at a frequency of about 1-1000 Hz (including 10 Hz, 100 Hz, 200 Hz, 500 Hz or any other frequency in between). The irradiation time is about 1 second to 60 minutes (including 5 sec, 10 sec, 20 sec, 50 sec, 100 sec, 200 sec, 500 sec, 1000 sec or any other time in between). It will be appreciated that irradiation times can be selected based upon the thickness of the material to be irradiated and the type of UV lamp (e.g., Xe excimer lamp, Mercury lamp) used for the irradiation. After UV irradiation, gases in the process chamber 26 are evacuated from the exhaust port 44. Thus semiconductor processing apparatus 10 carries out the above series of processing steps according to an automatic sequence, which is programmed into a controller 46. In some embodiments, the processing steps include the introduction of gas into the process chamber, the irradiation of low-k material on a substrate with UV light, the stopping of irradiation, and the stopping of gas flow into the process chamber.

Embodiments of the invention can be applied to cure various low-k materials known in the art. Preferred embodiments of the invention have particular advantages when applied to low-k materials containing silicon, oxygen and carbon atoms. Without being limited by theory, it is believed that, in a typical UV curing process, the UV light irradiation breaks —CH₃ bonds and —Si—O bonds in the low-k material, reestablishes the —Si—O bonds, and builds an O—Si—O network, thereby improving the mechanical strength of the low-k material. The atmosphere in which the substrate is irradiated has typically been an inert gas atmosphere, which has been used to prevent oxidation of the low-k material. N₂, He, Ar, among other inert gases known in the art, can be used as the inert gas.

The Si—O and Si—CH₃ bonds in the low-k material are broken by the UV irradiation, and Si is caused to again bond with 0 to form a O—Si—O network by exposure to heat in the process chamber, and thus mechanical strength is increased. However, it has been found that the silicon atoms can also bond with H or OH, and thus form Si—H and Si—OH bonds, which have been found to be undesirable for low-k materials. For example, without being limited by theory, —Si—H and —SiOH groups are believed to be a cause of moisture absorption and oxidation in low-k materials, which brings about an increased dielectric constant and stress change over time. Curing the low-k film without producing such substituents is desired from the point of view of stability of the film and maintaining a low dielectric constant.

Advantageously, it has been found that providing CO₂ in the curing atmosphere, where the curing atmosphere has a CO₂ concentration of about 1-16% by volume, causes the release of —H and —OH as H₂O from the low-k material, while also maintaining the dielectric constant of the low-k material at a low value. Thus, the production of —Si—H and —SiOH groups is suppressed. Moreover, the CO₂ aids the formation of Si—O bonds, thereby increasing the curing efficiency (the time required to produce a desired curing of the low-k material) relative to a UV curing process without CO₂. For example, the curing efficiency can advantageously be increased by about 10% or more.

### EXAMPLE

Aurora ULK™ films (developed by ASM Japan, K.K., Tokyo Japan), were provided on a plurality of substrates. The Aurora ULK™ films are low-k films having a dielectric constant of about 2.6. The films were cured by exposure to UV light emitted from a Xe excimer lamp. The films were cured at a temperature of 400° C. and a pressure of 5 Torr for 60 seconds. The atmosphere in the curing chamber consisted of a mixture of N₂ and CO₂. CO₂ was added to an N₂ process chamber atmosphere to arrive at various concentrations of CO₂ in the process chamber atmosphere. The resulting cured films where analyzed by infrared spectroscopy and their dielectric constants and elastic modulus were measured.

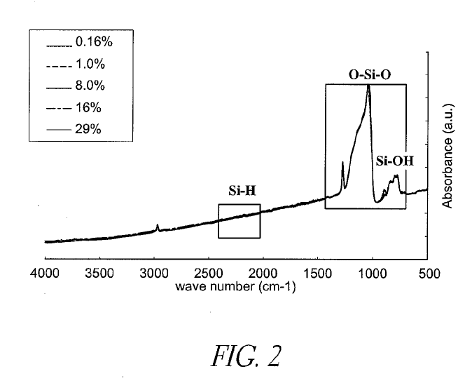

FIG. 2 combines various FT-IR spectrographs taken after curing the low-k dielectric films in atmospheres containing various levels of CO₂. As shown in FIG. 2, relatively large peaks near 900 cm⁻¹ indicate the presence of Si—OH groups in the cured low-k films. Peaks near 2200 cm⁻¹ indicate the presence of Si—H groups.

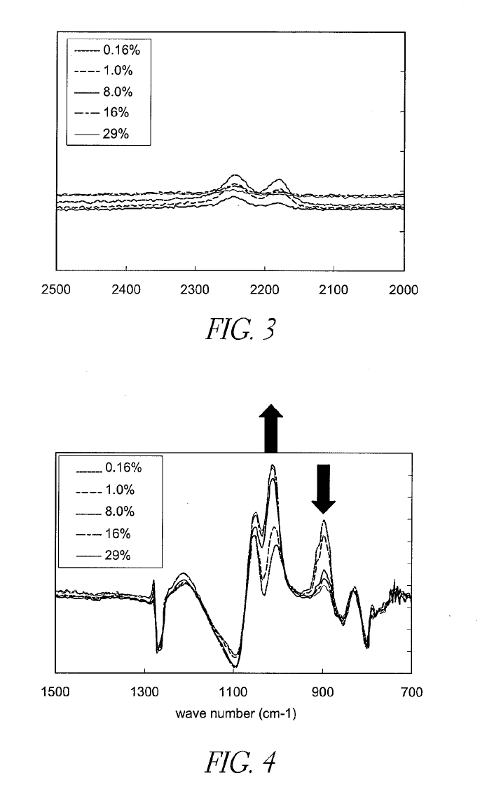

To more easily see how UV curing alters the cured low-k dielectric films, FIGS. 3 and 4 show the FT-IR spectrographs of the low-k dielectric films after taking a difference of the FT-IR spectrographs before and after UV curing. FIGS. 3 and 4 show enlargements of various regions of the FT-IR spectrographs. It can be seen that as the CO₂ concentration is increased, the peaks near 900 cm and 2200 cm⁻¹ decrease, and the peaks near 1000 and 1050 cm⁻¹ grow. It will be appreciated that the peaks near 1000 and 1050 cm⁻¹ indicate the presence of O—Si—O bonds. Advantageously, these Figures indicate that adding CO₂ suppresses the production of Si—H and Si—OH groups. On the other hand, it can be seen that the O—Si—O bond, which is the basic structure of the low-k film, was increased.

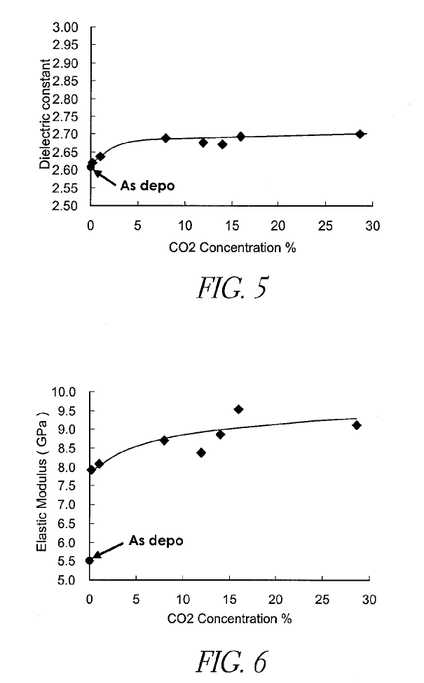

It will be appreciated that incorporation of carbon into low-k materials, e.g., carbon-doping of low-k materials, has been used to decrease the dielectric constant of low-k materials. Carbon-containing low-k materials are discussed in U.S. Pat. No. 6,514,880 and U.S. Pat. No. 7,144,620, the entire disclosures of which are incorporated herein by reference. However, it has been found that UV curing in an atmosphere containing CO₂ can cause the dielectric constant of the UV-cured material to increase, rather than decrease. With reference to FIG. 5, the presence of CO₂ in the UV curing atmosphere was found to increase the dielectric constant of the low-k film. Advantageously, however, the increases were small and could be limited by, e.g., maintaining the CO₂ concentration below 16%.

With reference to FIG. 6, the presence of CO₂ in the UV curing atmosphere was found to increase the elastic modulus of the low-k film. Advantageously, the EM value is observed to continue to increase up to a CO₂ concentration of about 16%. Without being limited by theory, it is believed that the increase in O—Si—O bonds (FIG. 4) due to the presence of CO₂ increases the EM value up to the 16% concentration level.

It will also be appreciated by those skilled in the art that various omissions, additions and modifications may be made to the methods and structures described above without departing from the scope of the invention. All such modifications and changes are intended to fall within the scope of the invention, as defined by the appended claims.

We claim:

1. A method for semiconductor processing, comprising:
providing a low dielectric constant film on a substrate in a process chamber;
curing the low dielectric constant film by irradiating the low dielectric constant film with UV light; and
exposing the low dielectric constant film to a process gas having about 1-16% CO₂ by volume during curing the low dielectric constant film.

2. The method of claim 1, wherein the process gas has about 1-5% CO₂ by volume.

3. The method of claim 1, wherein the process gas is formed of inert gas mixed with the CO₂.

4. The method of claim 2, wherein the inert gas is selected from the group consisting of N₂, He or Ar.

5. The method of claim 1, wherein exposing the low dielectric constant film comprises suppressing the formation of —Si—H groups.

6. The method of claim 1, wherein exposing the low dielectric constant film comprises suppressing the formation of —Si—OH groups.

7. The method of claim 1, wherein the low dielectric constant film is formed of organosilicate glass.

8. The method of claim 1, wherein exposing the low dielectric constant film to the process gas is performed using UV light with a wavelength of about 100-400 nm, an intensity of about 1-1000 mW/cm² for between about 1 second and about 20 minutes.

9. The method of claim 8, wherein exposing the low dielectric constant film to the process gas comprises maintaining a temperature in the process chamber between about 0 and 650° C. and a pressure in the process chamber between about 0.1 Torr and about 1000 Torr.

10. The method of claim 1, wherein irradiating the low dielectric constant film with UV light comprises exposing the low dielectric constant film to a plurality of pulses of UV light at a frequency of between about 1 and about 1000 Hz.

11. A method for integrated circuit fabrication, comprising:
providing a substrate in a process chamber having a process chamber atmosphere with a CO₂ concentration between about 1% and about 16%, the substrate having an exposed low dielectric constant material;
irradiating the low dielectric constant material with UV light to form Si—O bonds while suppressing formation of —Si—H and —Si—OH groups relative to UV light irradiation of the low dielectric constant material in an atmosphere consisting of inert gas; and
reacting the low dielectric constant material with CO₂ while irradiating the low dielectric constant material, thereby releasing H₂O from the low dielectric constant material.

12. The method of claim 11, wherein the UV light has a wavelength of about 190 nm or less.

13. The method of claim 11, wherein curing the low dielectric constant material maintains a dielectric constant of the low dielectric constant material at about 2.80 or less.

14. The method of claim 11, wherein an elastic modulus of the low dielectric constant material is about 8.0 GPa or more.

15. The method of claim 11, wherein the low dielectric constant material comprises silicon, carbon and oxygen atoms.

16. The method of claim 11, wherein curing the low dielectric constant material comprises forming a —O—Si—O— network.

17. The method of claim 11, wherein the low dielectric constant material has a dielectric constant of about 4 or less.

18. A system for semiconductor processing, comprising:
a UV radiation chamber having a UV light source;
a source of CO₂ in gas communication with the UV radiation chamber; and
a controller programmed to irradiate a low dielectric material in the UV radiation chamber with UV light while maintaining a concentration of CO₂ in the UV radiation chamber between about 1 and about 16% by volume.

19. The system of claim 18, wherein the UV light source is a UV lamp.

20. The system of claim 18, wherein the UV lamp is a mercury lamp.

21. The system of claim 18, wherein the controller is programmed to maintain an atmosphere comprising CO₂ and inert gas in the UV radiation chamber while irradiating the low dielectric material with UV light.

22. The system of claim 18, wherein the controller is programmed to maintain a concentration of CO₂ in the UV radiation chamber at about 1-5% by volume while irradiating the low dielectric material.
